(19) United States
(12) Patent Application Publication
(10) Pub. No.: US 2008/0050521 A1
(43) Pub. Date: Feb. 28, 2008

(54) Apparatus & method for vapor phase lubrication of recording media with reduced lubricant consumption

(75) Inventors: Xiaoding Ma, Fremont, CA (US); Michael J. Stimiman, Fremont, CA (US); Jing Gui, Fremont, CA (US)

Correspondence Address: SEAGATE TECHNOLOGY LLC;c/o MCDERMOTT WILL & EMERY LLP, 600 13TH STREET, NW, WASHINGTON, DC, 20005-3096, US

(73) Assignee: SEAGATE TECHNOLOGY LLC

(21) Appl. No.: 11/508,843

(22) Filed: Aug. 24, 2006

(51) Int. Cl. C23C 16/00

(52) U.S. Cl. 427/248.1; 118/715

(57) ABSTRACT

A vapor source for depositing a thin film of polymeric lubricant on a magnetic or MO recording medium comprises an enclosure comprised of at least one thermally conductive material and including a back wall and a front wall spaced apart by at least one sidewall thereby defining a chamber with an interior space, the front wall comprising a plurality of openings forming a vapor diffusion plate with an array of vapor orifices; at least one liquid reservoir within the interior space for containing a vaporizable liquid material; a heater for heating the interior space and forming a vapor of the liquid material; and a shutter device for controlling flow of vapor through the orifices of the vapor diffusion plate, thereby reducing lubricant consumption.

### FIELD OF THE INVENTION

The present invention relates to apparatus and method for uniformly applying a thin film of a lubricant to substrate surfaces in a solventless manner. The invention has particular utility in the manufacture of magnetic or magneto-optical (“MO”) data/information storage and retrieval media comprising a stack of thin film layers formed on suitable substrates, e.g., disc-shaped substrates, wherein a thin lubricant topcoat is applied to the upper surface of the layer stack for improving tribological performance of the media when utilized with read/write transducers operating at very low flying heights.

### BACKGROUND OF THE INVENTION

Magnetic and MO media are widely employed in various applications, particularly in the computer industry for data/information storage and retrieval purposes. A magnetic medium in e.g., disc form, such as utilized in computer-related applications, comprises a disc-shaped non-magnetic substrate, e.g., of glass, ceramic, glass-ceramic composite, polymer, metal, or metal alloy, typically an aluminum (Al)-based alloy such as aluminum-magnesium (Al—Mg), having at least one major surface on which a stack of thin film layers constituting the medium are sequentially deposited. Such layers may include, in sequence from the substrate deposition surface, a plating layer, e.g., of amorphous nickel-phosphorus (Ni—P), a polycrystalline underlayer, typically of chromium (Cr) or a Cr-based alloy such as chromium-vanadium (Cr—V), a magnetic layer, e.g., of a cobalt (Co)-based alloy, and a protective overcoat layer, typically of a carbon (C)-based material having good tribological properties. A similar situation exists with MO media, wherein a layer stack is formed on a substrate deposition surface, which layer stack comprises a reflective layer, typically of a metal or metal alloy, one or more rare-earth thermo-magnetic (RE-TM) alloy layers, one or more transparent dielectric layers, and a protective overcoat layer, for functioning as reflective, transparent, writing, writing assist, and read-out layers, etc.

Thin film magnetic and MO media in disc form, such as described supra, are typically lubricated with a thin film of a polymeric lubricant, e.g., a perfluoropolyether, to reduce wear of the disc when utilized with data/information recording and read-out heads/transducers operating at low flying heights, as in a hard disc system functioning in a contact start-stop (“CSS”) mode. Conventionally, a thin film of lubricant is applied to the disc surface(s) during manufacture by dipping a disc with a stack of thin film layers formed thereon, including at least one recording layer, into a bath containing a small amount of lubricant, e.g., less than about 1% by weight of a fluorine-containing polymer, dissolved in a suitable solvent, typically a perfluorocarbon, fluorohydrocarbon, or hydrofluoroether. However, a drawback inherent in such dipping process is the consumption of large quantities of solvent, resulting in increased manufacturing cost and concern with environmental hazards associated with the presence of toxic or otherwise potentially harmful solvent vapors in the workplace.

Another drawback associated with the conventional dipping method for applying a thin film of a polymeric lubricant to a substrate results from the lubricant materials being mixtures of long chain polymers, with a distribution of molecular weights. Since the molecular weight of the polymeric lubricant affects the mechanical (i.e., tribological) performance of the head-disc interface, it is common practice to subject the polymeric lubricant mixtures (as supplied by the manufacturer) to a fractionation process prior to adding the lubricant to the solvent in order to obtain a fraction having a desired molecular weight distribution providing optimal tribological performance. However, such pre-fractionation undesirably adds an additional step and increases the overall process cost.

Vapor deposition of thin film lubricants is an attractive alternative to dip lubrication in view of the above drawbacks. Specifically, vapor deposition of lubricant films is advantageous in that it is a solventless process and the process for generating the lubricant vapor can simultaneously serve for fractionating the lubricant mixture into a desired molecular weight distribution, thereby eliminating the need for a pre-fractionation step. Moreover, vapor deposition techniques can provide up to about 100% bonded lubricant molecules when utilized with appropriate polymeric lubricants and magnetic and/or MO disc substrates having deposition surfaces comprised of a freshly-deposited carbon-based protective overcoat layer which is not exposed to air prior to lubricant deposition thereon.

U.S. Pat. No. 6,183,831 B1 issued Feb. 6, 2001, the entire disclosure of which is incorporated herein by reference, discloses a static vapor deposition apparatus (Intevac VLS 100 system, Intevac Corp., Santa Clara, Calif.) for applying a thin layer of polymeric lubricant to a thin film data/information storage and retrieval medium, e.g., in disc form, utilizing a static process/system, wherein a single disc-shaped substrate is moved (e.g., by means of a disc lifter) to a position facing the orifices of a pair of oppositely facing lubricant vapor sources and maintained at that position while the lubricant film is deposited on the disc surfaces, with the lubricant film thickness being determined (i.e., controlled) by the length of the interval during which the disc surfaces face the orifices of the respective lubricant vapor sources. A diffuser plate for the lubricant vapor is provided intermediate the lubricant vapor source and the substrate surface in order to control the spatial distribution, hence thickness uniformity, of the lubricant thin films obtained with such static vapor deposition process/apparatus at deposition rates of from about 1 to about 10 Å/sec. for providing lubricant film thicknesses up to about 50 Å.

U.S. Pat. No. 6,613,151 B1 issued Sep. 2, 2003 (commonly assigned with the present invention), the entire disclosure of which is incorporated herein by reference, discloses pass-by apparatus and methodology for eliminating, or at least minimizing, limitations/drawbacks associated with the above-described static vapor deposition means and methodology, as well as the requirement for use of multiple lubricant vapor sources and/or vapor diffuser plates in the manufacture of disc-shaped magnetic and MO recording media. According to the “pass-by” lubricant vapor deposition apparatus and methodology disclosed therein, at least one substrate (e.g., a disc-shaped recording medium) is continuously moved past the lubricant vapor source(s) for lubricant thin film deposition on the surface(s) thereof. As a consequence, non-uniformity of the lubricant thin film thickness arising from the static positioning of the substrates relative to the lubricant vapor source is eliminated, or at least minimized. In addition, thickness uniformity of the lubricant thin films is enhanced by providing the lubricant vapor source(s) in elongated form with a length greater than the maximum dimension of the substrate deposition surface, e.g., disc diameter, with a plurality of slit-like nozzles for providing an even distribution of lubricant vapor.

More specifically, according to U.S. Pat. No. 6,613,151 B1, a modular lubricant thin film or additive vapor deposition system is provided which utilizes a “pass-by” deposition method, as opposed to the “static” methodology of U.S. Pat. No. 6,183,831 B1. The material to be deposited (e.g., lubricant or additive) is contained in a closed, elongated, heated chamber having a length greater than the substrate maximum dimension, and allowed to expand through a plurality of narrow slits, i.e., nozzles, into a deposition chamber maintained at a reduced pressure, e.g., from about 10⁻⁵ to about 10⁻⁹ Torr by a vacuum pump means. Substrates, e.g., discs, carried by a transport or conveyor mechanism are passed in front of and in close proximity to the nozzles. The substrates are “passed-by” the nozzles in a continuous motion, i.e., without stopping to provide a static interval over the lubricant vapor source as in conventional processing, thereby eliminating both of the above-mentioned sources of lubricant thickness non-uniformity inherent in the static deposition system. The deposition rate of the lubricant or additive is readily controlled by appropriate variation of any combination of “pass-by” speed, lubricant vapor pressure, and nozzle slit width, such that a desired lubricant or additive film thickness is obtained during one or more passes by one or more lubricant vapor sources.

When vapor deposition of both sides of a dual-surfaced substrate is required, e.g., as with disc-shaped substrates, the apparatus is provided with first and second similarly configured and opposingly positioned lubricant vapor sources, with the nozzle slits of the second vapor sources being offset from those of the first vapor sources. According to a cylindrically configured embodiment of a “pass-by” vapor deposition apparatus, substrates are transported in a circular path past at least one elongated, radially extending vapor deposition source positioned transversely with respect to the substrate path, the apparatus comprising a cylindrically-shaped deposition chamber with a curved sidewall portion and upper and lower circularly-shaped end walls defining an interior space. A vacuum pump or equivalent means maintains the interior space of the chamber at a reduced pressure below atmospheric pressure, e.g., from about 10⁻⁵ to about 10⁻⁹ Torr. A combined substrate load/unload station or equivalent means (either being of conventional design) is provided on one of the upper or lower end walls for insertion of fresh substrates into the interior space of the deposition chamber for vapor deposition onto at least one surface thereof and for removal of vapor-deposited substrates from the interior space. The chamber is further provided with a substrate transporter/conveyor means, e.g., a radially extending arm controllably rotatable about an axis coaxial with the central axis of the upper and lower end walls and equipped at a remote end thereof with a substrate support means, e.g., a disc gripper or equivalent means, for sequentially transporting/conveying a fresh substrate introduced into the interior space of the deposition chamber via a substrate load/unload station and past at least one, preferably a plurality of elongated, spaced-apart, radially extending lubricant/additive vapor sources for “pass-by” vapor deposition onto at least a first surface of the moving substrate. Coated substrates are withdrawn from the deposition chamber via a substrate load/unload station after “pass-by” deposition thereon from at least one vapor source.

Each lubricant/additive vapor source is comprised of a closed, heated, elongated chamber for accommodating therein a quantity of liquid lubricant to be thermally vaporized, the chamber having a length greater than the maximum dimension of the substrate deposition surface, e.g., the disc diameter. The wall of the chamber facing the substrate deposition surface is provided with a plurality of narrow slits forming nozzles for creating a vapor stream directed toward a facing surface of the substrate for condensation thereon as a thin film. In the event a second, opposite surface of the substrate is to receive a vapor deposited lubricant or additive layer, the deposition chamber is provided in like manner with at least one similarly constituted vapor source with a plurality of narrow, nozzle-forming slits facing the second surface. In such instance, the nozzle-forming slits of the vapor sources on opposite sides of the substrate may be offset, if necessary, and a cooled surface provided opposite the slits for condensation of excess lubricant or additive vapor, in order to prevent contamination of deposition chamber.

U.S. Pat. No. 6,808,741 B1 issued Oct. 26, 2004 (commonly assigned with the present invention), the entire disclosure of which is incorporated herein by reference, discloses another pass-by apparatus and method for eliminating, or at least minimizing, limitations/drawbacks associated with conventional cassette-based, single disc, static lubricant vapor deposition methodology/apparatus utilized in the automated manufacture of disc-shaped magnetic and MO recording media, e.g., poor lubricant film thickness, reduced product throughput, contamination of neighboring process chambers or modules of an in-line system, variation of average MW of the deposited polymeric lubricant over time, unequal thermal histories of substrates conveyed in cassettes, and the requirement for removal from and reinsertion of substrates into the cassettes. According to the “pass-by” lubricant vapor deposition apparatus and methodology disclosed therein, a plurality of disc-shaped substrates (rather than a single substrate) are continuously moved past at least one linearly elongated lubricant vapor source for lubricant thin film vapor deposition on at least one surface thereof. As a consequence, thickness uniformity of the deposited lubricant thin films and product throughput rates are significantly improved vis-à-vis the single disc methodology and apparatus described above. In addition, improved, elongated lubricant vapor sources effectively eliminate problems and difficulties associated with temporal changes in the polymer lubricant fractionation process which occur as the lubricant liquid volume is reduced during system operation via vaporization.

The apparatus and methodology of U.S. Pat. No. 6,808,741 B1 provide uniform thickness lubricant thin films by means of vapor deposition, at rates consistent with the requirements of automated manufacturing processing, while retaining the advantages of vapor deposition of the lubricant thin films, including, inter alia, solventless processing, elimination of the requirement for pre-fractionation of the polymeric lubricant materials to obtain a desired molecular weight distribution, and obtainment of very high percentages of bonded lubricant when utilized in modular form in the automated manufacture of magnetic and/or MO recording media with freshly deposited carbon-based protective overcoat layers thereon, e.g., as when the carbon-containing protective overcoat layer is deposited in a system module downstream from (i.e., before) the lubricant vapor deposition module and transported to the latter without atmospheric contact, as in an in-line, continuous system.

According to this disclosure, a modular lubricant thin film vapor deposition apparatus forms part of a continuous, in-line manufacturing system, and utilizes a “pass-by” deposition method, as opposed to the “static” method described above. The lubricant material to be deposited is contained in a vapor source comprising a closed, elongated, heated vapor source chamber having a length much greater than the maximum dimension of individual substrates/workpieces, and allowed to vaporize and exit the vapor source chamber via a linear array of orifices forming nozzles which create a linearly elongated stream of lubricant vapor. Typically, the elongated vapor source chamber with the linear array of orifices is vertically oriented and positioned within the interior space of a deposition chamber maintained at a reduced pressure, e.g., from about 10⁻⁵ to about 10⁻⁹ Torr by a suitable vacuum pump means. The deposition chamber is elongated in a direction transverse to the direction of elongation of the vapor source, whereby a plurality of substrates/workpieces, e.g., discs for magnetic or MO recording media, carried and moved in a vertical orientation by a mounting/supporting means (e.g., a perforated pallet) and a transport/conveyor mechanism, are passed in front of and in close proximity to the linearly elongated vapor source/vapor stream. The plurality of substrates/workpieces are “passed by” the linearly arrayed orifices of the elongated vapor source in a continuous motion, i.e., without stopping as in conventional processing to provide a static interval when directly opposite the lubricant vapor source, thereby eliminating disadvantages/drawbacks inherent in static processing which contribute to lubricant thickness non-uniformity. In addition, the “pass-by” method according to the disclosure, wherein a substantial plurality of substrates/workpieces is processed, rather than a single substrate/workpiece as in conventional “static” processing, provides a significant increase in product throughput vis-à-vis the conventional method/apparatus, eliminates any requirement for transfer of individual substrates/workpieces from and to cassettes, and utilizes substrates/workpieces with similar thermal histories. Moreover, lubricant thin films are conveniently simultaneously formed on opposing sides of substrates/workpieces, e.g., discs for magnetic and/or MO recording media, by providing the deposition chamber with at least a pair of spaced-apart, linearly elongated vapor sources positioned in parallel, facing relation, and utilizing a substrate/workpiece mounting/supporting means (e.g., a vertically oriented perforated pallet) which is transported in the space between the facing vapor sources, thereby exposing the opposing surfaces of the substrates/workpieces to respective linearly elongated lubricant vapor streams. In addition, the deposition rate of the lubricant is readily controlled, as by appropriate variation of any combination of “pass-by” speed, lubricant vapor pressure, orifice diameter, etc., such that a desired lubricant film thickness is obtained.

More specifically, the apparatus comprises a series of linearly elongated, vacuum chambers interconnected by gate means of conventional design, including a centrally positioned deposition chamber including at least one, preferably a pair of spaced-apart, opposingly facing, linearly elongated lubricant vapor sources, and a pair of buffer/isolation chambers at opposite lateral ends of the central deposition chamber for insertion and withdrawal, respectively, of a plurality of vertically oriented substrates/workpieces, e.g., a plurality disc-shaped substrates carried by substrate/workpiece mounting/support means, typically a perforated, flat planar pallet including conventional means for releasably mounting and supporting the disc-shaped substrates such that each of the opposing surfaces thereof faces a respective linearly elongated lubricant vapor source during “pass-by” transport. Respective chambers connected to the distal ends of the inlet and outlet buffer/isolation chambers are provided for use of the apparatus as part of a larger, continuously operating, in-line apparatus wherein substrates/workpieces receive antecedent and/or subsequent processing.

The apparatus is provided with conventional vacuum means for maintaining the interior spaces of each of the constituent chambers at a reduced pressure below atmospheric pressure, e.g., from about 10⁻⁵ to about 10⁻⁹ Torr, and is further provided with a substrate/workpiece conveyor/transporter means of conventional design for linearly transporting the substrate/workpiece mounting/supporting means through the respective gate means from chamber-to-chamber in its path through the apparatus.

In operation of such linearly configured, in-line apparatus in the manufacture of magnetic and/or MO recording media, a plurality of substrates/workpieces carried by a suitable mounting/supporting means, typically annular disc-shaped substrates releasably carried by a vertically oriented perforated pallet, are subjected to processing in the continuous, in-line apparatus to deposit on at least one surface thereof a layer stack constituting the recording medium, the outermost layer of the stack comprising a freshly coated carbon-containing protective overcoat. The thus-prepared substrates are carried on the pallet and transferred without atmospheric contact, via a connecting chamber, to the entrance buffer/isolation chamber of the above-described apparatus, transported to the central vapor deposition chamber for “pass-by” lubricant vapor deposition thereon, as described in some detail above, and then transported to the exit buffer/isolation chamber for removal or transfer of lubricant-coated substrates via another connecting chamber to a further in-line apparatus for subsequent/additional processing. After completion of all processing and exiting of the pallet from the apparatus, the discs are removed therefrom and the pallet reused with another plurality of substrates.

Generally, the deposition rate of the lubricant vapor is controlled by regulating the temperature of the heated lubricant contained in the vapor source, and vapor phase lubrication processing as described supra typically affords a number of advantages vis-à-vis conventional dip-coating, including solvent-free processing and more uniform lubricant thicknesses. However, design deficiencies of the currently available lubricant vapor sources result in several disadvantages in vapor phase lubrication processing of recording media. Specifically, according to current practice, the lubricant vapor continuously diffuses out from the interior space of the source via openings in a front wall which function as orifices for lubricant vapor and as a diffusion plate. As a consequence, outward diffusion of lubricant vapor occurs even when a disc is not positioned opposite the orifices for deposition thereon. Since the interval for deposition of a lubricant layer of desired or requisite thickness on a given disc is shorter than the idle or transport interval between consecutive discs, a significant amount of lubricant vapor exiting the source is not deposited on the disks, resulting in unnecessary consumption (loss), of expensive lubricant, thereby incurring an economic disadvantage.

Another disadvantage associated with current practice results from heating only a back wall of the enclosure of the vapor source, whereby other portions of the enclosure, e.g., transversely extending sidewalls, are at a lower temperature during operation. As a consequence of this unequal heating, there is a tendency for lubricant build-up to occur on the inner surfaces of the lower temperature walls, e.g., the aforementioned sidewalls. This results in higher lubricant consumption compared to conventional dip-lubricant coating processing, along with attendant higher material-per-disc cost.

In view of the foregoing, there exists a clear need for improved means and methodology for depositing thin films of a lubricant, e.g., a polymeric lubricant, by vapor techniques and at deposition rates consistent with the throughput requirements of automated manufacturing processing, e.g., of magnetic and/or MO data/information storage and retrieval media, which means and methodology overcome the above-described drawbacks and disadvantages of the static and or “pass-by” lubricant vapor deposition technology utilizing currently available lubricant vapor sources. More specifically, there exists a need for improved means and methodology for vapor depositing thin films of lubricant (e.g., a polymeric lubricant) which provides improved lubricant consumption (i.e., utilization) and economic competitiveness in the automated manufacture of such magnetic and/or MO media.

The present invention addresses and solves problems and difficulties in achieving increased lubricant utilization by means of vapor deposition techniques, e.g., thin film polymeric lubricant deposition on disc substrates utilized in the manufacture of magnetic and/or MO media, while maintaining full capability with all aspects of conventional automated manufacturing technology therefor. Further, the means and methodology afforded by the present invention enjoy diverse utility in the manufacture of various other devices and articles requiring deposition of uniform thickness thin film lubricant layers thereon.

### DISCLOSURE OF THE INVENTION

An advantage of the present invention is an improved vapor source.

Another advantage of the present invention is an improved vapor source for use in depositing uniform thickness films of polymeric lubricant on recording media surfaces for improving tribological properties thereof.

Still another advantage of the present invention is an improved apparatus for performing static vapor deposition of lubricant thin films.

Yet another advantage of the present invention is an improved apparatus for performing pass-by vapor deposition of lubricant thin films.

A further advantage of the present invention is an improved method of performing vapor deposition.

A still further advantage of the present invention is an improved method of depositing uniform thickness films of polymeric lubricant on recording media surfaces for improving tribological properties thereof.

Additional advantages and other aspects and features of the present invention will be set forth in the description which follows and in part will become apparent to those having ordinary skill in the art upon examination of the following or may be learned from the practice of the present invention. The advantages of the present invention may be realized and obtained as particularly pointed out in the appended claims.

According to an aspect of the present invention, the foregoing and other advantages are obtained in part by an improved vapor source comprising:

(a) an enclosure comprised of at least one thermally conductive material, the enclosure including a back wall and a front wall spaced apart by at least one sidewall and defining a chamber with an interior space, the front wall comprising a plurality of openings extending therethrough and forming a vapor diffusion plate with an array of vapor orifices;

(b) at least one liquid reservoir within the interior space of the chamber and adapted for containing a quantity of a vaporizable liquid material therein;

(c) a heater for heating the interior space of the chamber and forming therein a vapor of the liquid material; and

(d) a shutter device for controlling flow of the vapor through the plurality of orifices of the vapor diffusion plate.

According to embodiments of the present invention, the plurality of openings form a linearly extending array of vapor orifices; and the source comprises a plurality of liquid reservoirs within the interior space, each adapted for containing a quantity of the vaporizable liquid material therein.

Preferably, each of the plurality of liquid reservoirs is adjacent the back wall of the enclosure and integrally formed therewith.

Embodiments of the present invention include those wherein the shutter device comprises at least one shutter positioned at at least one of the following locations: within the interior space of the chamber adjacent the at least one reservoir; within the interior space of the chamber adjacent an interior face of the front wall; and adjacent an exterior face of the front wall.

According to embodiments of the present invention include those wherein the heater is adapted for heating the backwall and the at least one sidewall for minimizing accumulation of the liquid on interior surfaces of the at least one sidewall. Preferably, the heater is in thermal contact with exterior surfaces of the back wall and the at least one sidewall.

Another aspect of the present invention is an improved apparatus for performing static vapor deposition of a thin film of a material on at least one surface of a substrate, comprising at least one vapor source as described above.

Yet another aspect of the present invention is an apparatus for performing pass-by vapor deposition of a thin film of a material on at least one surface of at least one substrate, comprising at least one vapor source as described above.

A further aspect of the present invention is an improved method of vapor depositing a thin film of a material on at least one surface of at least one substrate, comprising steps of:

(a) providing an apparatus comprising:
(i) a chamber having an interior space maintained below atmospheric pressure;
(ii) a substrate holder for supplying the interior space with at least one substrate and for withdrawing the at least one substrate from the interior space; and
(iii) at least one vapor source for supplying the interior space with a flow of vapor of the material, the at least one vapor source including a shutter device for regulating the flow of the vapor into the interior space;

(b) supplying the interior space with at least one substrate having at least one surface;

(c) depositing a predetermined thickness film of the material on the at least one surface of the at least one substrate, the depositing comprising utilizing the shutter device for limiting the flow of the vapor from the source to a predetermined interval; and

(d) withdrawing the at least one substrate from the interior space.

According to certain embodiments of the present invention, step (c) comprises performing the depositing while the at least one substrate remains statically positioned relative to the at least one vapor source; whereas, according to other embodiments of the present invention, step (c) comprises performing the depositing while the at least one substrate continuously moves past the at least one vapor source.

Preferably, step (a) comprises providing an apparatus including at least one vapor source for supplying a vapor of a lubricant material; and step (b) comprises supplying a substrate for a data/information storage/retrieval medium. More preferably, step (a) comprises providing an apparatus including at least one vapor source for supplying a vapor of a polymeric fluorine-containing lubricant material; and step (b) comprises supplying a substrate for a disc-shaped magnetic or magneto-optical (MO) recording medium.

According to preferred embodiments of the present invention, step (a) comprises providing an apparatus including a vapor source comprising:

(i) an enclosure comprised of at least one thermally conductive material, the enclosure including a back wall and a front wall spaced apart by at least one sidewall and defining a chamber with an interior space, the front wall comprising a plurality of openings extending therethrough and forming a vapor diffusion plate with an array of vapor orifices;

(ii) at least one liquid reservoir within the interior space of the chamber and adapted for containing a quantity of a vaporizable liquid material therein; and

(iii) a heater for heating the interior space of the chamber and forming therein a vapor of the liquid material; wherein the shutter device controls flow of the vapor through the plurality of orifices of the vapor diffusion plate.

Preferably, the plurality of openings in the front wall form a linearly extending array of vapor orifices; and the vapor source comprises a plurality of liquid reservoirs integrally formed with the back wall of the enclosure, each adapted for containing a quantity of the vaporizable liquid material therein.

According to preferred embodiments of the invention, the shutter device comprises at least one shutter positioned at at least one of the following locations: within the interior space of the chamber adjacent the at least one reservoir; within the interior space of the chamber adjacent an interior face of the front wall; and adjacent an exterior face of the front wall.

Further preferred embodiments of the invention include those wherein the heater is adapted for heating the backwall and the at least one sidewall for minimizing accumulation of the liquid on interior surfaces of the at least one sidewall, as when the heater is in thermal contact with exterior surfaces of the back wall and the at least one sidewall.

Additional advantages and aspects of the present invention will become readily apparent to those skilled in the art from the following detailed description, wherein embodiments of the present invention are shown and described, simply by illustration of the best mode contemplated for practicing the present invention. As will be described, the present invention is capable of other and different embodiments, and its several details are susceptible of modification in various obvious respects, all without departing from the spirit of the present invention. Accordingly, the drawings and description are to be regarded as illustrative in nature, and not as limitative.

### BRIEF DESCRIPTION OF THE DRAWINGS

The following detailed description of the embodiments of the present invention can best be understood when read in conjunction with the following drawings, in which the various features are not necessarily drawn to scale but rather are drawn as to best illustrate the pertinent features, in which like reference numerals are employed throughout to designate similar features, wherein:

FIG. 1 is a simplified, schematic cross-sectional top view of an embodiment of an in-line, pass-by lubricant vapor deposition apparatus according to the present invention;

FIG. 2 is a simplified, schematic cross-sectional side view of the in-line, pass-by lubricant vapor deposition apparatus according to the embodiment of the present invention shown in FIG. 1;

FIG. 3 is a simplified, schematic cross-sectional side view of a linearly extended lubricant vapor source usable in the static and/or “pass-by” lubricant vapor deposition apparatuses such as described above;

FIG. 4 is a simplified, schematic cross-sectional side view of a lubricant vapor source according to an embodiment of the present invention and usable in the static and/or “pass-by” lubricant vapor deposition apparatuses such as described above; and

FIG. 5 is a simplified, schematic cross-sectional side view of a lubricant vapor source according to a further embodiment of the present invention.

### DESCRIPTION OF THE INVENTION

The present invention is based upon recognition by the inventors that the above-described disadvantages and drawbacks associated with the available vapor sources for vapor depositing thin films of a material, e.g., a polymeric lubricant, on substrate surfaces, e.g., magnetic and/or MO media substrates. Specifically, according to current practice as described above, the lubricant vapor continuously diffuses out from the interior space of the source via openings in a front wall which function as orifices for lubricant vapor and as a diffusion plate. As a consequence, outward diffusion of lubricant vapor occurs even when a disc is not positioned opposite the orifices for deposition thereon. Since the interval for deposition of a lubricant layer of desired or requisite thickness on a given disc is shorter than the idle or transport interval between consecutive discs, a significant amount of lubricant vapor exiting the source is not deposited on the disks, resulting in unnecessary consumption (loss), of expensive lubricant, thereby incurring an economic disadvantage. In addition, according to current practice, only a back wall of the enclosure of the vapor source is heated, whereby other portions of the enclosure, e.g., transversely extending sidewalls, are at a lower temperature during operation. As a consequence of this unequal heating, there is a tendency for lubricant build-up to occur on the inner surfaces of the lower temperature walls, e.g., the aforementioned sidewalls. This results in higher lubricant consumption compared to conventional dip-lubricant coating processing, along with attendant higher material-per-disc cost.

According to the invention, the above-described disadvantages and drawbacks associated with use of currently available vapor sources are eliminated, or at least minimized, by providing the vapor deposition apparatus or system with at least one improved vapor source including a shutter device for limiting flow of vapor therefrom to a predetermined interval necessary for depositing a thin film of desired thickness. As a consequence, unnecessary consumption of expensive coating material, e.g., fluorine-based polymeric lubricants utilized in the manufacture of magnetic and MO recording media, is eliminated or at least substantially reduced, thereby improving the economic competitiveness of vapor deposition processing in the automated fabrication of such products. In addition, according to the present invention, modification of the heater configuration of the vapor source effectively eliminates, or at least minimizes, accumulation of liquid material on portions of the source which do not contribute to vapor generation, e.g., sidewalls of the source.

The utility and advantageous performance of the improved vapor source according to the present invention will now be described in detail with respect to an in-line type pass-by apparatus such as disclosed in U.S. Pat. No. 6,808,741 B1 described above. However, it should be emphasized that the improved vapor source of the present invention is not limited to use with such linearly configured apparatus, but rather may be utilized to advantage in any of the above-described types of vapor deposition apparatus and systems, including, but not limited to, static, circularly configured pass-by, and linearly configured pass-by apparatus and systems.

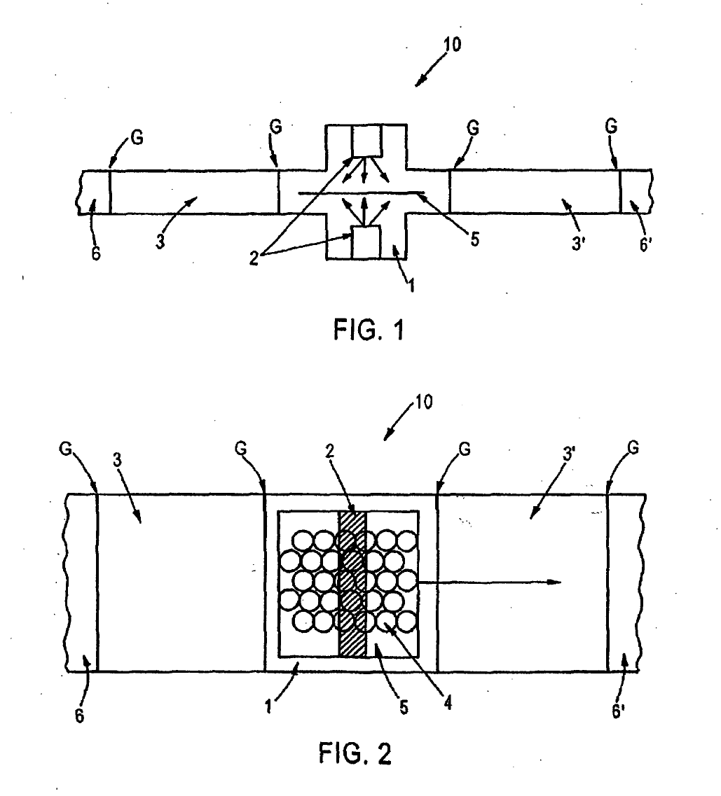

Referring now to FIGS. 1-2, shown therein, in simplified, schematic cross-sectional top and side views, respectively, is an embodiment of an in-line, “pass-by” lubricant vapor deposition apparatus 10, which apparatus can form a module of a larger, in-line apparatus for continuous, automated manufacture of, e.g., magnetic and/or magneto-optical (MO) recording media such as hard disks, and wherein a plurality of substrates/workpieces (e.g. disks) are transported in a linear path transversely past at least one linearly elongated lubricant vapor source for deposition of a thin film of lubricant on at least one surface of each of the plurality of substrates.

More specifically, apparatus 10 comprises a series of linearly elongated, vacuum chambers interconnected by gate means G of conventional design, including a centrally positioned deposition chamber 1 including at least one, preferably a pair of spaced-apart, opposingly facing, linearly elongated lubricant vapor sources 2, and a pair of buffer/isolation chambers 3, 3′ at opposite lateral ends of central deposition chamber 1 for insertion and withdrawal, respectively, of a plurality of vertically oriented substrates/workpieces, illustratively a plurality disc-shaped substrates 4 carried by substrate/workpiece mounting/support means 5, e.g., a perforated, flat planar pallet including conventional means (not shown in the drawing for illustrative simplicity) for releasably mounting/supporting the disc-shaped substrates 4 such that each of the opposing surfaces thereof faces a respective linearly elongated lubricant vapor source 2 during “pass-by” transport. Chambers 6, 6′ respectively connected to the distal ends of inlet and outlet buffer/isolation chambers 3, 3′ are provided for use of apparatus 10 as part of a larger continuously operating, in-line apparatus wherein substrates/workpieces 4 receive processing antecedent and/or subsequent to processing in apparatus 10.

Apparatus 10 is provided with conventional vacuum means (not shown in the drawing for illustrative simplicity) for maintaining the interior spaces of each of the constituent chambers 1, 3, 3′, etc. at a reduced pressure below atmospheric pressure, e.g., from about 10⁻⁵ to about 10⁻⁹ Torr, and is further provided with a substrate/workpiece conveyor/transporter means of conventional design (not shown in the drawings for illustrative simplicity) for linearly transporting substrate/workpiece mounting/supporting means 5 through the respective gate means G from chamber-to-chamber in its travel through apparatus 10.

As indicated above, according to a preferred embodiment of the present invention of particular utility in the manufacture of disc-shaped magnetic and/or MO recording media, the substrates/workpieces 4 carried by the substrate/workpiece mounting/supporting means 5 are in the form of annular discs, with inner and outer diameters corresponding to those of conventional hard disc-type magnetic and/or MO media, and the central, deposition chamber 1 of apparatus 10 is provided with a pair of opposingly facing, linearly extending vapor deposition sources 2 for deposition of a lubricant thin film on each surface of each of the plurality of discs carried by the perforated pallet mounting/supporting means 5.

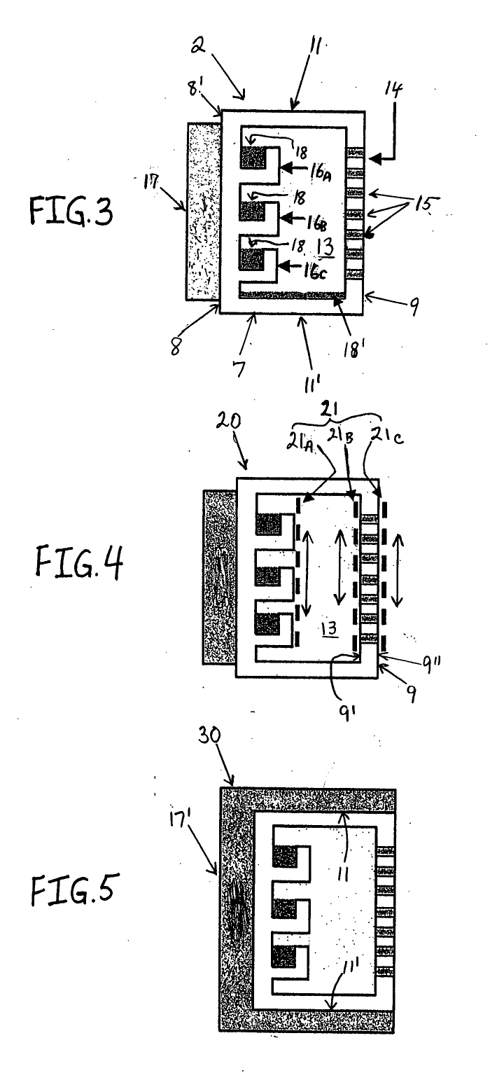

Referring to FIG. 3, shown therein, in simplified, schematic cross-sectional side view, is a linearly extended lubricant vapor source 2 for use in linearly configured (“in-line”) apparatus 10 or in any of the static and/or “pass-by” lubricant vapor deposition apparatuses described above. As illustrated, linearly extended lubricant vapor source 2 comprises an enclosure (illustratively, but not limitatively, a rectangular shaped enclosure) 7 including a back wall 8 and a front wall 9 connected by longitudinally extending sidewalls (illustratively sidewalls 11, 11′) forming a chamber with an interior space 13. The front wall 9 of the linearly extending enclosure 7 functions as a diffusion plate 14 and is provided with an array of spaced-apart openings 15, which openings 15 form orifices for lubricant vapor exiting the chamber formed by enclosure 7. As should be evident from FIG. 1, a linearly extending array of substantially equally spaced openings or orifices 15 allows formation of a linearly extending vapor stream extending for a significant portion of the length (vertical dimension) of enclosure 7. Each of the walls comprising vapor source enclosure 7 is fabricated of a high thermal conductivity material, e.g., a metal such as copper.

Mounted at spaced locations along the inner surface of back wall 8 of enclosure 7 (or integrally formed therewith) are a plurality of liquid lubricant reservoirs, illustratively, but not limitatively, lubricant reservoirs 16_{A}, 16_{B}, and 16_{C}, each fabricated from a block of thermally conductive material, e.g., a metal such as copper. At least one heater element 17, typically an electrical resistance heater, is mounted on or within the outer surface 8′ of the back wall 8 of enclosure 7 for heating and vaporizing liquid lubricant 18 contained in each of the reservoirs 16_{A}, 16_{B}, and 16_{C}. Thermocouples (not shown in the figure for illustrative simplicity) are also provided in order to control the temperature of the vapor source as to maintain a constant lubricant vapor flux.

Generally, the deposition rate of the lubricant vapor is controlled by regulating the temperature of the at least one heater element 17, and vapor phase lubrication processing as described supra typically affords a number of advantages vis-à-vis conventional dip-coating, including solvent-free processing and more uniform lubricant thicknesses. However, design deficiencies of a vapor source such as source 2 result in several disadvantages in vapor phase lubrication processing of recording media. Specifically, according to the current design of the lubricant vapor source 2, the lubricant vapor continuously diffuses out from the interior space of the source via the openings 15 in the front wall 9 functioning as orifices for lubricant vapor and forming a diffusion plate 14. As a consequence, outward diffusion of lubricant vapor occurs even when a disc is not positioned opposite the orifices for deposition thereon. Since the interval for deposition of a lubricant layer of desired or requisite thickness on a given disc is shorter than the idle or transport interval between consecutive discs, a significant amount of lubricant vapor exiting the source is not deposited on the disks, resulting in unnecessary consumption (loss), of expensive lubricant, thereby incurring an economic disadvantage.

Another disadvantage associated with a lubricant vapor source, such as source 2, results from placement of the heater element 17 on or within the back wall 8′ of enclosure 7. Since the heater element 17 contacts only the back wall of the enclosure or reservoir, the transversely extending sidewalls (illustratively sidewalls 11, 11′) are at a lower temperature than that of the back wall 8 and liquid reservoirs 16_{A}, 16_{B}, and 16_{C} during operation, and, as a consequence, there is a tendency for a quantity of lubricant build-up 18′ to occur on the inner surfaces of the sidewalls (illustratively along the interior surface of sidewall 11′. This phenomenon also results in higher lubricant consumption compared to conventional dip-lubricant coating processing, along with attendant higher material-per-disc cost.

Adverting to FIG. 4, shown therein, in simplified, schematic cross-sectional side view, is an improved lubricant vapor source 20 according to an embodiment of the present invention and usable in any of the static and/or “pass-by” lubricant vapor deposition apparatuses described above. As illustrated, vapor source 20 is similar in essential respect to vapor source 2 shown in FIG. 3, but is provided with a shutter device 21 for regulating/controlling flow of vapor outwardly from the interior space 13 of the source to the exterior. According to embodiments of the invention, shutter device 21 comprises at least one shutter positioned at at least one of the following locations: shutter 21_{A} located within the interior space 13 of the chamber adjacent the output end of each liquid reservoir 16_{A}, 16_{B}, and 16_{C}; shutter 21_{B} located within the interior space 13 of the chamber adjacent interior face 9′ of the front wall 9; and shutter 21_{C} located adjacent exterior face 9″ of the front wall 9. As shown in the figure, each shutter 21_{A}, 21_{B}, and 21_{C} is vertically movable (as by conventional means not shown in the drawing for illustrative simplicity) to controllably block outward flow of vapor toward the exterior of the source.

Operation of in-line, pass-by apparatus 10 provided with the improved vapor source(s) 20 according to the invention involves controllable actuation of at least one shutter 21_{A}, 21_{B}, and 21_{C} of each source to effectuate vapor flow therefrom for selected (predetermined) intervals consistent with deposition of thin films of selected (predetermined) thickness. Controllable actuation of the shutters for permitting vapor outflow to occur only during desired intervals is accomplished in conventional manner, e.g., by means of a control unit and solenoid devices, pneumatic actuators, etc., not shown in the drawing for illustrative simplicity. The inventive apparatus and methodology therefore effect significant reduction in consumption of expensive liquid material, e.g., fluorine-based polymericant lubricant, by limiting outflow of vapor from the vapor source to only that amount required for forming a thin film of requisite thickness, thereby enhancing cost-effectiveness of the vapor deposition processing.

Referring to FIG. 5, shown therein, in simplified, schematic cross-sectional side view, is an improved lubricant vapor source 30 according to a further embodiment of the present invention. According to this embodiment, heater element 17 of the sources shown in FIGS. 3 and 4, limited to contact with the exterior surface 8′ of back wall 8, is replaced with “wrap-around” heater element 17′ which extends over and in contact with the exterior surfaces of sidewalls 11 and 11′, thereby providing increased heating area and effectively eliminating any temperature differentials between the back and side walls of enclosure 7. As a consequence, condensation of vaporized liquid on cooler interior surfaces of source 30 is eliminated, or at least minimizing, thereby further reducing liquid utilization inefficiency. Preferably, the feature (i.e., heater configuration) of the embodiment of FIG. 5 is utilized together with the shutter feature of FIG. 4 to provide vapor sources of optimal lubricant usage efficiency.

The present invention thus provides a number of advantages over conventional vapor deposition apparatus and methodology, and is of particular utility in cost-effective automated manufacturing processing of thin film magnetic and MO recording media requiring deposition of uniform thickness lubricant topcoat layers for obtaining improved tribological properties. Specifically, the present invention provides for lubricant deposition with substantially reduced lubricant consumption vis-à-vis vapor deposition apparatus and methodology utilizing vapor sources which emit vapor continuously and include temperature gradients resulting in vapor condensation on interior surfaces of the source. Further, the inventive apparatus and methodology can be readily utilized as part of conventional manufacturing apparatus/technology in view of their full compatibility with all other aspects of automated manufacture of magnetic and MO media. Finally, the inventive apparatus and methodology are broadly applicable to a variety of vapor deposition processes utilized in the manufacture of a number of different products, e.g., mechanical parts, gears, linkages, etc., requiring lubrication.

In the previous description, numerous specific details are set forth, such as specific materials, structures, processes, etc., in order to provide a better understanding of the present invention. However, the present invention can be practiced without resorting to the details specifically set forth. In other instances, well-known processing materials, structures, and techniques have not been described in detail in order not to unnecessarily obscure the present invention.

Only the preferred embodiments of the present invention and but a few examples of its versatility are shown and described in the present invention. It is to be understood that the present invention is capable of use in various other embodiments and is susceptible of changes and/or modifications within the scope of the inventive concept as expressed herein.

What is claimed is:

1. A vapor source comprising:
(a) an enclosure comprised of at least one thermally conductive material, said enclosure including a back wall and a front wall spaced apart by at least one sidewall and defining a chamber with an interior space, said front wall comprising a plurality of openings extending therethrough and forming a vapor diffusion plate with an array of vapor orifices;
(b) at least one liquid reservoir within said interior space of said chamber and adapted for containing a quantity of a vaporizable liquid material therein;
(c) a heater for heating said interior space of said chamber and forming therein a vapor of said liquid material; and
(d) a shutter device for controlling flow of said vapor through said plurality of orifices of said vapor diffusion plate.

2. The source according to claim 1, wherein:
said plurality of openings form a linearly extending array of vapor orifices.

3. The source according to claim 1, comprising:
a plurality of liquid reservoirs within said interior space, each adapted for containing a quantity of said vaporizable liquid material therein.

4. The source according to claim 3, wherein:
each of said plurality of liquid reservoirs is adjacent said back wall of said enclosure.

5. The source according to claim 4, wherein:
each of said plurality of liquid reservoirs is integrally formed with said back wall of said enclosure.

6. The source according to claim 1, wherein said shutter device comprises at least one shutter positioned at at least one of the following locations:
(i) within said interior space of said chamber adjacent said at least one reservoir;
(ii) within said interior space of said chamber adjacent an interior face of said front wall; and
(iii) adjacent an exterior face of said front wall.

7. The source according to claim 1, wherein:
said heater is adapted for heating said backwall and said at least one sidewall for minimizing accumulation of said liquid on interior surfaces of said at least one sidewall.

8. The source according to claim 7, wherein:
said heater is in thermal contact with exterior surfaces of said back wall and said at least one sidewall.

9. An apparatus for performing static vapor deposition of a thin film of a material on at least one surface of a substrate, comprising at least one vapor source according to claim 1.

10. An apparatus for performing pass-by vapor deposition of a thin film of a material on at least one surface of at least one substrate, comprising at least one vapor source according to claim 1.

11. A method of vapor depositing a thin film of a material on at least one surface of at least one substrate, comprising steps of:
(a) providing an apparatus comprising:
(i) a chamber having an interior space maintained below atmospheric pressure;
(ii) a substrate holder for supplying said interior space with at least one substrate and for withdrawing said at least one substrate from said interior space; and
(iii) at least one vapor source for supplying said interior space with a flow of vapor of said material, said at least one vapor source including a shutter device for regulating said flow of said vapor into said interior space;
(b) supplying said interior space with at least one substrate having at least one surface;
(c) depositing a predetermined thickness film of said material on said at least one surface of said at least one substrate, said depositing comprising utilizing said shutter device for limiting said flow of said vapor from said source to a predetermined interval; and
(d) withdrawing said at least one substrate from said interior space.

12. The method as in claim 11, wherein:
step (c) comprises performing said depositing while said at least one substrate remains statically positioned relative to said at least one vapor source.

13. The method as in claim 11, wherein:
step (c) comprises performing said depositing while said at least one substrate continuously moves past said at least one vapor source.

14. The method as in claim 11, wherein:
step (a) comprises providing an apparatus including at least one vapor source for supplying a vapor of a lubricant material; and
step (b) comprises supplying a substrate for a data/information storage/retrieval medium.

15. The method as in claim 14, wherein:
step (a) comprises providing an apparatus including at least one vapor source for supplying a vapor of a polymeric fluorine-containing lubricant material; and
step (b) comprises supplying a substrate for a disc-shaped magnetic or magneto-optical (MO) recording medium.

16. The method as in claim 11, wherein step (a) comprises providing an apparatus including a vapor source comprising:
an enclosure comprised of at least one thermally conductive material, said enclosure including a back wall and a front wall spaced apart by at least one sidewall and defining a chamber with an interior space, said front wall comprising a plurality of openings extending therethrough and forming a vapor diffusion plate with an array of vapor orifices;
at least one liquid reservoir within said interior space of said chamber and adapted for containing a quantity of a vaporizable liquid material therein; and
a heater for heating said interior space of said chamber and forming therein a vapor of said liquid material; wherein:
said shutter device controls flow of said vapor through said plurality of orifices of said vapor diffusion plate.

17. The method as in claim 16, wherein:
said plurality of openings form a linearly extending array of vapor orifices; and
said vapor source comprises a plurality of liquid reservoirs integrally formed with said back wall of said enclosure, each adapted for containing a quantity of said vaporizable liquid material therein.

18. The method as in claim 16, wherein:
said shutter device comprises at least one shutter positioned at at least one of the following locations:
(i) within said interior space of said chamber adjacent said at least one reservoir;
(ii) within said interior space of said chamber adjacent an interior face of said front wall; and
(iii) adjacent an exterior face of said front wall.

19. The method as in claim 16, wherein:
said heater is adapted for heating said backwall and said at least one sidewall for minimizing accumulation of said liquid on interior surfaces of said at least one sidewall.

20. The method as in claim 19, wherein:
said heater is in thermal contact with exterior surfaces of said back wall and said at least one sidewall.
